(19) United States
(12) Patent Application Publication
(10) Pub. No.: US 2004/0145372 A1
(43) Pub. Date: Jul. 29, 2004

(54) Ground fault detection circuit detecting whether a switching regulator's power output node is grounded

(75) Inventor: Katsumi Miyazaki, Hyogo (JP)

Correspondence Address: BURNS DOANE SWECKER & MATHIS L L P, POST OFFICE BOX 1404, ALEXANDRIA, VA, 22313-1404, US

(73) Assignees: RENESAS TECHNOLOGY CORP; RENESAS DEVICE DESIGN CORP.

(21) Appl. No.: 10/657,252

(22) Filed: Sep. 9, 2003

(30) Foreign Application Priority Data
Jan. 29, 2003 (JP) 2003-020385(P)

(51) Int. Cl. G01R 31/14

(52) U.S. Cl. 324/509

(57) ABSTRACT

A switching regulator includes a ground fault detection circuit including: a p channel MOS transistor, a resistor and a diode together allowing a high frequency current to be supplied to a power output node; an inverter outputting a signal of the high level when the output node's potential exceeds a predetermined potential; and a D-type flip-flop set in response to the inverter outputting a signal of the high level to set an activation signal φE high to activate a control circuit. When the power output node is grounded the control circuit is not activated and no overcurrent flows.

### BACKGROUND OF THE INVENTION

1. Field of the Invention

The present invention relates generally to ground fault detection circuits and particularly to those detecting whether a power output node of a switching regulator that is located between a power transistor and an inductor is grounded.

2. Description of the Background Art

In a switching regulator when a power output node, a potential output node or the like is grounded, an overcurrent flows, resulting in destroying the switching regulator, its peripheral equipment and the like. Such an overcurrent has conventionally been prevented by a variety of proposed methods, which is categorized for example into: (1) employing a fuse; (2) detecting a current; and (3) detecting a voltage (see Japanese Patent Laying-Open Nos. 2001-37244, 6-169526 and 10-70832 for example).

However, these methods all have an advantage and a disadvantage. While methods (1) and (2) ensure that overcurrent is prevented, they are costly. Method (3) can be implemented at low cost. In this method, however, an output current is once converted to a voltage and in response to the voltage exceeding a predetermined threshold value an output transistor is turned off. As such, a self positive feedback circuit configuration is compulsively introduced and the switching regulator's normal operation would adversely be affected. Furthermore, method (3) is also disadvantageous as a current-voltage conversion sensor's characteristics vary.

### SUMMARY OF THE INVENTION

Therefore the present invention mainly contemplates an inexpensive ground fault detection circuit capable of accurately detecting whether a switching regulator's power output node is grounded.

The present ground fault detection circuit detects whether a power output node of a switching regulator that is located between a power transistor and an inductor is grounded. The ground fault detection circuit includes a current supply circuit supplying the power output node with a pulsed current continuously, and a determination circuit determining from a potential of the power output node whether the power output node is grounded. As such, regardless of a load circuit's resistance value, whether the power output node is grounded can accurately be detected, which contributes to a reduced device cost.

The foregoing and other objects, features, aspects and advantages of the present invention will become more apparent from the following detailed description of the present invention when taken in conjunction with the accompanying drawings.

### BRIEF DESCRIPTION OF THE DRAWINGS

In the drawings:

FIG. 1 is a circuit block diagram showing a configuration of a step down switching regulator of the present invention in a first embodiment; and

FIG. 2 is a circuit block diagram showing a configuration of a negative voltage generating switching regulator of the present invention in a second embodiment.

### DESCRIPTION OF THE PREFERRED EMBODIMENTS

First Embodiment

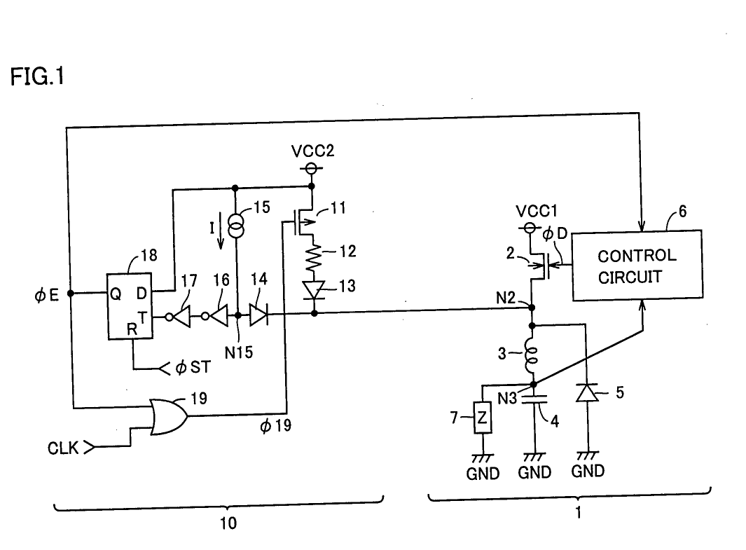

With reference to FIG. 1, a step down switching regulator includes a potential generation circuit 1 and a ground fault detection circuit 10. Potential generation circuit 1 applies a predetermined direct current (dc) potential to a load circuit 7. More specifically, potential generation circuit 1 includes an n channel MOS transistor 2, an inductor 3, a capacitor 4, a diode 5 and a control circuit 6. N channel MOS transistor (power transistor) 2 is connected between a first power supply voltage VCC1 line and a power output node N2 and has its gate receiving a drive clock signal φD from control circuit 6.

Inductor 3 is connected between power output node N2 and a potential output node N3. Capacitor 4 is connected between potential output node N3 and a ground potential GND line. Diode 5 has an anode connected to a ground potential GND line and a cathode to power output node N2. Load circuit 7 is connected between potential output node N3 and a ground potential GND line. Control circuit 6 is activated by an activation signal φE having a high level of an active level to control a duty ratio of drive clock signal φD to allow the potential output node N3 potential to attain a predetermined dc potential. Drive clock signal φD is a high frequency clock signal.

When signal φD is raised from the low level to the high level, n channel MOS transistor 2 conducts, and n channel MOS transistor 2 and inductor 3 have a gradually increasing current passing therethrough. When signal φD is caused to fall from the high level to the low level, n channel MOS transistor 2 does not conduct and diode 5 conducts, and diode 5 and inductor 3 have a gradually decreasing current flowing therethrough. Furthermore, from potential output node N3 via load circuit 7 a current flows out into a ground potential GND line. As such, by controlling a duty ratio of drive clock signal φD, the power output node N3 potential can be set to a predetermined dc potential lower than the first power supply potential VCC1.

Ground fault detection circuit 10 detects whether power output node N2 is grounded. If the node is grounded, ground fault detection circuit 10 sets activation signal φE to the low level of an inactive level. Otherwise the circuit sets the signal to the high level of an active level. More specifically, ground fault detection circuit 10 includes a p channel MOS transistor 11, a resistor 12, diodes 13, 14, a constant current circuit 15, inverters 16, 17, a D-type flip-flop 18 and an OR gate 19. P channel MOS transistor 11, resistor 12 and diode 13 are connected in series between a second power supply potential VCC2 line and power output node N2. P channel MOS transistor 11 has its gate receiving a signal φ19 output from OR gate 19. Diode 13 prevents a current from flowing back from power output node N2 to resistor 12.

Constant current circuit 15 allows a small constant current I to flow from the second power supply potential VCC line to node N15. Constant current I stabilizes the potential of a node N15. Node N15 is connected to power output node N2 via diode 14 and also to a clock terminal T of D-type flip-flop 18 via inverters 16, 17. Diode 14 prevents a current from flowing back from power output node N2 to node N15. Inverter 16 has a threshold voltage VTH set to be a predetermined voltage. Inverter 16 configures a potential detection circuit.

D-type flip-flop 18 has a reset terminal R receiving a signal φST, an input terminal D receiving the second power supply potential VCC2, and an output terminal Q outputting activation signal φE. OR gate 19 receives activation signal φE and a clock signal CLK and outputs signal φ19. Signal φST is a signal of an indication to turn on a bias potential of the entirety of a system including the switching regulator and is set to the high level of the active level after power supply potentials VCC1 and VCC2 rise. Clock signal CLK is a high frequency clock signal of a predetermined duty ratio (for example of 50%), although clock signal CLK of a square wave signal may be replaced with a triangular wave signal, a sine wave signal or the like.

The switching regulator operates, as will now be described hereinafter. When power potential VCC1, VCC2 are thrown, signal φST is raised to the high level of the active level, D-type flip-flop 18 is reset and activation signal φE is set to the low level of the inactive level. In response to signal φE set low, control circuit 6 is deactivated and drive clock signal φD is fixed low, and n channel MOS transistor 2 is fixed to be non-conducting.

Furthermore, when signal φE is set low, clock signal CLK passes through OR gate 19 to become signal φ19 and p channel MOS transistor 11 is turned on/off with a high frequency. When p channel MOS transistor 11 conducts, a current flows from the second power supply potential VCC2 line through p channel MOS transistor 11, resistor 12 and diode 13 into power output node N2. When p channel MOS transistor 11 does not conduct, power output node N2 does not have a current flowing thereinto.

When power output node N2 is not grounded, inductor 3 acting to block a high frequency allows the power supply output node N2 potential to rapidly increase. When the power output node N2 potential plus a threshold voltage VF of diode 14, i.e., the node N15 potential exceeds threshold voltage VTH of inverter 16, inverter 16 outputs a signal dropped from high to low and inverter 17 outputs a signal raised from low to high. Thus, D-type flip-flop 18 is set, activation signal φE is raised to the high level of the active level, and control circuit 6 is activated.

Control circuit 6 controls a duty ratio of drive clock signal φD to allow potential output node N3 to attain a predetermined dc potential. Furthermore when activation signal φE is set high OR gate 19 outputs signal φ19 fixed high and p channel MOS transistor 11 is fixed to be non-conducting. Furthermore, when potential output node N3 is caused to have a predetermined dc potential, the node N16 potential becomes higher than threshold voltage VTH of inverter 15, and inverter 17 outputs a signal fixed high and signal φE is fixed high.

When power output node N2 is grounded, p channel MOS transistor 11 turned on/off to supply power output node N2 with a high frequency current does not increase the power output node N2 potential. As such, inverter 17 outputs a signal continuing to have the low level, activation signal φE continues to have the low level, and control circuit 6 is fixed to be inactive. As such, when power output node N2 is grounded, n channel MOS transistor 2 is not turned on/off to pass an overcurrent.

In the first embodiment power output node N2 is supplied with a high frequency current and its potential is detected, and from the detection whether the node is grounded is detected. As such, whether power output node N2 is grounded can accurately be detected regardless of the resistance value of load circuit 7. If power output node N2 is supplied with a dc current and load circuit 7 is small in resistance, the power output node N2 potential cannot be increased and whether the node is grounded cannot accurately be detected.

Furthermore, inverter 16 having the predetermined threshold voltage VTH that is used to detect the power output node N2 potential contributes to a simplified configuration and a reduced device cost.

Furthermore, rectifier diodes 13, 14 allow potential generation circuit 1 and ground fault detection circuit 10 to be driven with different power supply potentials VCC1, VCC2, which is highly applicable.

Note that the present invention is intended to detect a ground fault of power output node N2 before initiation of the switching regulator to prohibit the initiation of the switching regulator, and it is not intended to detect a ground fault of power output node N2 caused when the switching regulator is operating.

However, power output node N2 of a switching regulator incorporated in a semiconductor integrate circuit device (LSI) is grounded mostly by short circuit of adjacent pins introduced for example by leakage of solder used to mount the LSI on a substrate. The node can also be grounded by a metal piece adhering to the node as a result of roughly handling a casing of a product including the LSI. In any of the cases, the present invention can prevent overcurrent. In a switching regulator protected by a casing sealed from therearound that is in operation, power output node N2 is grounded with a probability significantly smaller than in the above two cases. As such the present invention is a significantly effective method of preventing an overcurrent attributed to a ground fault of power output node N2.

Second Embodiment

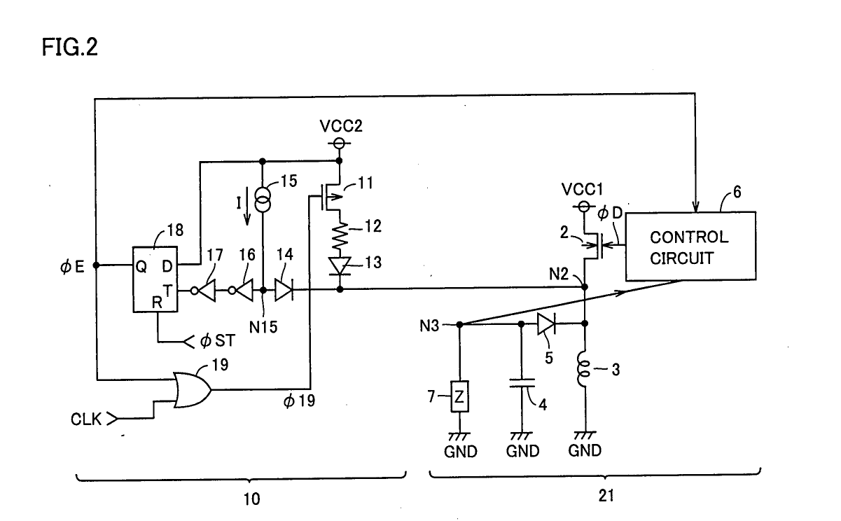

FIG. 2 is a circuit block diagram showing a configuration of a negative potential generating, switching regulator of the present invention in a second embodiment. As shown in the figure, this switching regulator differs from the FIG. 1 switching regulator in that potential generation circuit 1 is replaced with a potential generation circuit 21, which corresponds to potential generation circuit 1 with inductor 3 and diode 5 replaced by each other. Inductor 3 is connected between power output node N2 and a ground potential GND line. Diode 5 has an anode connected to potential output node N3 and a cathode to power output node N2. Control circuit 6 is activated in response to activation signal φE having the high level of the active level to control a duty ratio of drive clock signal φD to allow potential output node N3 to attain a predetermined negative potential.

When signal φD is raised from the low level to the high level, n channel MOS transistor 2 conducts, and n channel MOS transistor 2 and inductor 3 have a gradually increasing current passing therethrough. When signal φD is caused to fall from the high level to the low level, n channel MOS transistor 2 does not conduct and diode 5 conducts, and diode 5 and inductor 3 have a gradually decreasing current flowing therethrough. Furthermore, from a ground potential GND line via load circuit 7 a current flows out into potential output node N3. As such, by controlling a duty ratio of drive clock signal φD, the power output node N3 potential can be set to a predetermined negative potential. The remainder of the configuration and operation is identical to that of the switching regulator of the first embodiment.

The second embodiment can also provide the same effect as the first embodiment.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A ground fault detection circuit detecting whether a power output node of a switching regulator located between a power transistor and an inductor is grounded, comprising:
a current supply circuit supplying said power output node with a pulsed current continuously; and
a determination circuit determining from a potential of said power output node whether said power output node is grounded.

2. The ground fault detection circuit according to claim 1, wherein said current supply circuit includes:
a transistor having a first electrode receiving a power supply potential and a gate electrode receiving a clock signal;
a resistor having one electrode connected to a second electrode of said transistor; and
a first diode having an anode connected to the other electrode of said resistor, and a cathode connected to said power output node.

3. The ground fault detection circuit according to claim 1, wherein said determination circuit includes:
a potential detection circuit having an input node connected to said power output node, outputting a signal of a first logical level for a potential of said input node lower than a predetermined potential, and outputting a signal of a second logical level for a potential of said input node higher than the predetermined potential; and
a flip-flop set in response to said potential detection circuit outputting said signal of said second logical level to output a signal indicating that said power output node is not grounded.

4. The ground fault detection circuit according to claim 3, further comprising a second diode having an anode connected to said input node of said potential detection circuit, and a cathode connected to said power output node.

5. The ground fault detection circuit according to claim 4, further comprising a constant current circuit supplying said anode of said second diode with a predetermined current.

6. The ground fault detection circuit according to claim 3, wherein said current supply circuit stops supply of the pulsed current in response to said flip-flop outputting the signal indicating that said power output node is not grounded.
